(19) United States
(12) Patent Application Publication
(10) Pub. No.: US 2006/0255417 A1
(43) Pub. Date: Nov. 16, 2006

(54) Image sensor having embedded lens

(75) Inventor: Hwa-Yong Kang, Suwon-si (KR)

Correspondence Address: CHA & REITER, LLC, 210 ROUTE 4 EAST STE 103, PARAMUS, NJ, 07652, US

(73) Assignee: Samsung Electronics Co., LTD

(21) Appl. No.: 11/403,770

(22) Filed: Apr. 13, 2006

(30) Foreign Application Priority Data
May 10, 2005 (KR) 38863/2005

(51) Int. Cl. H01L 31/0232

(52) U.S. Cl. 257/432

(57) ABSTRACT

Disclosed is an image sensor. The image sensor includes a substrate, at least one insulation layer formed on the substrate, and a plurality of pixels formed on the substrate, each of which includes a photodiode region formed on the substrate for performing an optical-electric conversion, a first lens formed on the at least one insulation layer for converging incident light, and a second lens embedded in the at least one insulation layer so as to be disposed between the photodiode region and the first lens for converging the incident light.

### CLAIM OF PRIORITY

This application claims the benefit of the earlier filing date, pursuant to 35 USC 110(e) to that patent application entitled “Image Sensor Having Embedded Lens”, filed in the Korean Intellectual Property Office on May 10, 2005 and assigned Patent Application Serial No. 2005-0038863, the contents of which are incorporated herein by reference.

### BACKGROUND OF THE INVENTION

1. Field of the Invention

The present invention relates to an image sensor having a plurality of pixels, and more particularly to an image sensor in which each pixel has a lens to improve the light reception efficiency.

2. Description of the Related Art

The frequency of use of complementary metal-oxide-semiconductor (CMOS) image sensor has increased in camera modules included in recent mobile products.

The CMOS image sensor is a device which converts light in an inputted visual region into electric signals so as to record the associated image. The image sensor includes a plurality of pixels, each of which includes a photodiode and a transistor. Meanwhile, each pixel cannot use its all allocated area as a light reception region, as some portion of the allocated area is assigned to the transistor. Therefore, the light reception area is reduced to an area that is as large as possible considering the area or region assigned to the transistor. In order to increase the light reception area, a technology has been developed in which a micro lens is disposed on an upper portion of each pixel, thereby improving the light reception efficiency of the pixels.

U.S. Pat. No. 6,821,810, assigned to Hsiao, et al. and entitled “High Transmittance Overcoat for Optimization of Long Focal Length Micro-lens Arrays in Semiconductor Color Imagers,” discloses an image sensor that includes a substrate on which a plurality of photodiode regions are formed, a metallization layer for electric connection formed on the substrate, a passivation layer and a planarization layer formed on the metallization layer, a color filter formed on the planarization layer, and a plurality of micro-lens formed on the color filter. The image sensor also includes a plurality of pixels having identical structures.

FIG. 1 is a sectional view showing a pixel of a conventional CMOS image sensor. The image sensor includes a substrate 110, and first, second, and third insulation layers 130, 140, and 150 formed on the substrate 110. The image sensor also includes a plurality of pixels 100 having identical structures.

Each pixel 100 is provided with a photodiode region 120 formed in substrate 110, first metal layers 132 and 134 formed on a non-photodiode area of substrate 110, a micro lens 160 formed on a third insulation layer 150 so as to be optically aligned with the photodiode region 120, and a color filter 155 disposed between the photodiode region 120 and the micro lens 160. The phrase “optical alignment” means that corresponding devices are aligned so as to be substantially symmetric with one another on an optical axis in a light propagating direction. At this time, a device having a plane surface must be aligned so that the surface of the device is substantially perpendicular to the optical axis.

The micro lens 160 has a convex-plane shape so as to converge incident light into the photodiode region 120.

The color filter 155 is a filter which transmits light of a certain or predetermined color, and filters the light converged by the micro lens 160.

For electric connection between the photodiode region 120 and transistors (not show), the first metal layers 132 and 134 are embedded in a first insulation layer 130, while second metal layers 142 and 144 are embedded in a second insulation layer 140.

The photodiode region 120 converts incident light 172 that is introduced into the center portion of photodiode region 120 into electric signals. The photodiode region 120 includes a PN junction for the optical-electric conversion.

In the above mentioned image sensor, however, the smaller each pixel becomes, the more the cross talk of signals between the adjacent pixels increases. Specifically, light 174, which is incident to the micro lens 160 so as to be incline against the axis of light and is not converged into the photodiode region 120, invades adjacent another pixel, thereby causing such cross talk. Moreover, when light 176, which is incident to an edge of the micro lens 160 (a portion farthest from the axis of light), is introduced into a side portion near a depletion layer of the photodiode region 120, random noise and image lag can be induced due to down-speed according to the diffusion of electric charges.

### SUMMARY OF THE INVENTION

Accordingly, the present invention has been made to solve the above-mentioned problems occurring in the prior art and provides additional advantages, by providing an image sensor which can improve the light reception efficiency and reduce cross talk between adjacent pixels.

According to the first embodiment of the present invention, there is provided an image sensor which comprises a substrate, at least one insulation layer formed on the substrate, and a plurality of pixels formed on the substrate, each of which includes a photodiode region formed on the substrate for performing an optical-electric conversion, a first lens formed on the insulation layer for converging incident light and a second lens embedded in the insulation layer so as to be disposed between the photodiode region and the first lens for converging the incident light.

### BRIEF DESCRIPTION OF THE DRAWINGS

The above features and advantages of the present invention will be more apparent from the following detailed description taken in conjunction with the accompanying drawings, in which:

FIG. 1 is a sectional view showing a pixel in a conventional complementary metal-oxide-semiconductor (CMOS) image sensor;

FIG. 2 is a sectional view showing a pixel in a complementary metal-oxide-semiconductor image sensor according to the preferred embodiment of the present invention;

FIG. 3 is a flowchart illustrating a process of manufacturing the complementary metal-oxide-semiconductor image sensor according to the preferred embodiment of the present invention; and

FIGS. 4 through 9 are views illustrating the process of manufacturing the CMOS image sensor shown in FIG. 3.

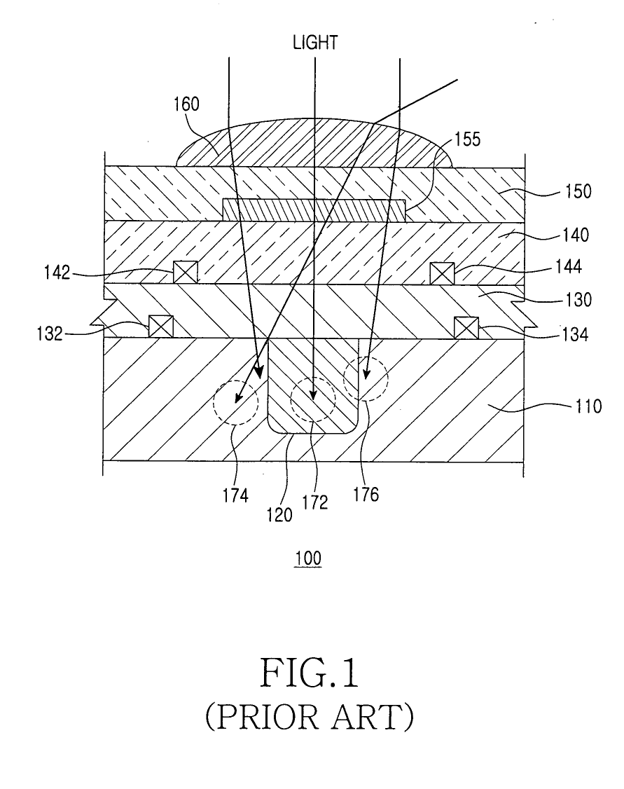

### DETAILED DESCRIPTION

Hereinafter, embodiments of the present invention will be described in detail with reference to the accompanying drawings. For the purposes of clarity and simplicity, a detailed description of known functions and configurations incorporated herein will be omitted to avoid making the subject matter of the present invention unclear.

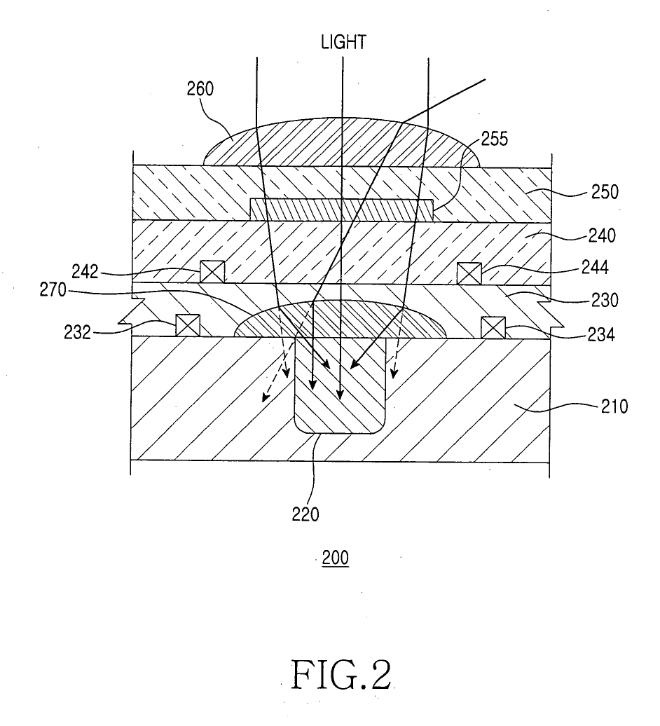

FIG. 2 is a sectional view showing a pixel in a CMOS image sensor according to the preferred embodiment of the present invention. The image sensor includes a substrate 210 and first, second and third insulation layers 230, 240, and 250, respectively, RES. Moreover, the image sensor has a plurality of pixels 200 of an identical structure. Each pixel 200 includes a photodiode region 220, a first lens 260, first metal electrodes 232 and 234, second metal electrodes 242 and 244, a color filter 255, and a second lens 270.

The photodiode region 220 is formed in substrate 210 and converts the incident light into electric signals. The photodiode region 220 includes a PN junction to convert incident light into the electric signals. Moreover, the photodiode region 220 may have an insulation layer on an upper portion thereof.

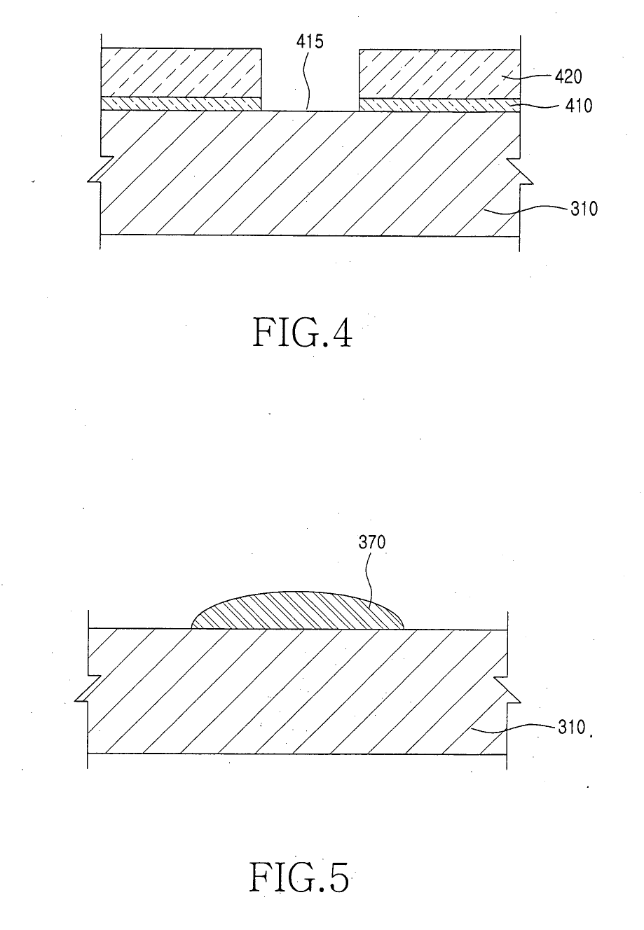

The second lens 270 is formed on the photodiode region 220 so as to fully cover the surface of the photodiode region 220. The second lens 270, which has a convex-plan shape, converges the incident light at the center portion of the photodiode region 220. The second or interior lens 270 may be formed through a local oxidation of a silicon patterning process and an oxidation process, as is more fully described with regard to FIGS. 4-9. The second or interior lens 270 is embedded in a first insulation layer 230 and is optically aligned with the photodiode region 220.

The first metal electrodes 232 and 234 are arranged on a non-photodiode region of insulator layer 230, and electrically connect the photodiode region 220 to transistors (not shown). The first metal electrodes 232 and 234 are embedded in the first insulation layer 230 so as to be substantially parallel with each other on both sides of the second lens 270.

The second metal electrodes 242 and 244 are arranged on a non-photodiode region of second insulation layer 240 and are to electrically connect the photodiode region 220 to transistors (not shown). The second metal electrodes 242 and 244 are embedded in the second insulation layer 240 so as to be far from a passage of light passing through the first lens 260.

The color filter 255 is disposed between the first lens 260 and the second lens 270, which is a filter for transmitting light having a predetermined color, as previously discussed. The color filter 255 filters the light converged by the first lens 260. The color filter 255 is embedded in the third insulation layer 250 so as to be disposed between the first and second lenses 260 and 270.

The first or exterior lens 260 is formed on the third insulation layer 250 so as to be substantially optically aligned with the second or interior lens 270 and converges incident light onto the surface of the second lens 270. The first lens 260 has a convex-plane shape.

The second or interior lens 270 converges the light collected by the first lens 260 at the center portion of the photodiode region 220, thereby reducing cross talk and improving the light reception efficiency. Furthermore, the curvature of the convex surface of the second lens 270 is controlled by adjusting the diameter of an opening of a mask during the local oxidation of silicon patterning process, so that the focal length of the first and second lenses 260 and 270 can be easily adjusted.

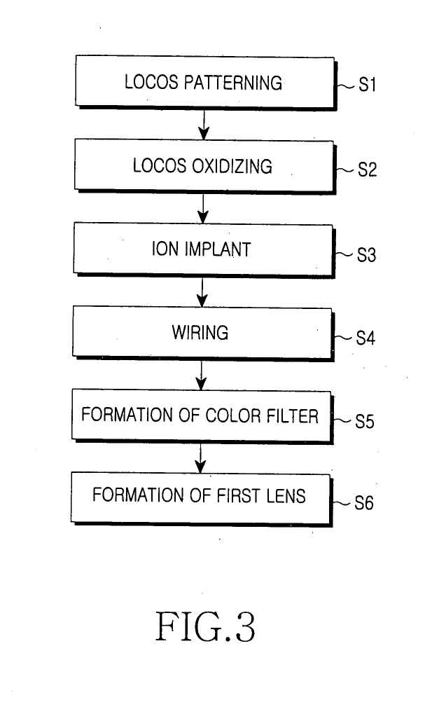

FIG. 3 is a flowchart illustrating a process of manufacturing the CMOS image sensor according to the preferred embodiment of the present invention. FIGS. 4 through 9 are views illustrating in further detail the process steps shown in FIG. 3 for manufacturing a CMOS image sensor in accordance the principles of the invention. The image sensor includes a plurality of pixels having the identical structure. Hereinafter, only one pixel will be described.

Referring to FIG. 4, the step S1 (of FIG. 3) represents a process of patterning the local oxidation of silicon. In the step S1, a SiNx mask 410 having an opening 415 is formed on the substrate 310 by using the photo-resist mask 420.

Referring to FIG. 5, the step S2 (of FIG. 3) represents a process of oxidizing a local oxidation of silicon. In the step S2, the second or interior lens 370 having the convex-plane shape is grown through a thermal oxidation process in the opening 415 of the SiNx mask 410.

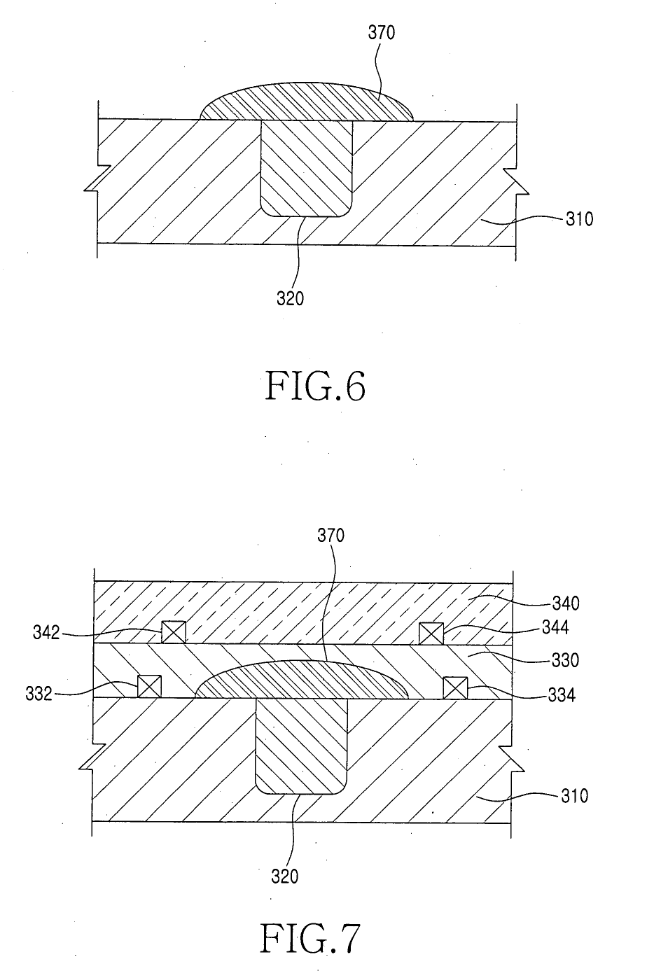

Referring to FIG. 6, the step S3 (of FIG. 3) represents is an ion implant process. In the step S3, a photodiode region 320 having a PN junction is formed in a region of the substrate 310 covered with the second lens 370.

Referring to FIG. 7, the step S4 (of FIG. 3) represents a process of electrically connecting the photodiode region 320 to the transistors (not shown). The step S4 includes two sub-steps as follows.

First, after the first metal electrodes 332 and 334 are formed on the non-photodiode region of the substrate 310, the first insulation layer 330 is formed on the substrate 310 in order to fully cover the first metal electrodes 332 and 334, and the second lens 370.

Secondly, after the second metal electrodes 342 and 344 are formed on the first insulation layer 330 so that the second metal electrodes 342 and 344 are disposed outside the photodiode region, the second insulation layer 340 is formed on the first insulation layer 330 so as to fully cover the second metal electrodes 342 and 344.

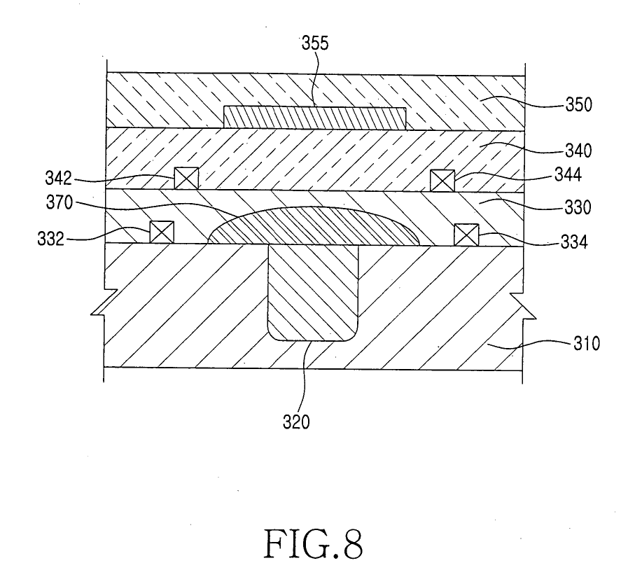

Referring to FIG. 8, the step S5 (of FIG. 3) represents a process of forming color filter and a third insulation layer 350. In the step S5, after the color filter 355 is formed on the second insulation layer 340, the third insulation layer 350 is formed on the second insulation layer 340 so as to fully cover the color filter 355.

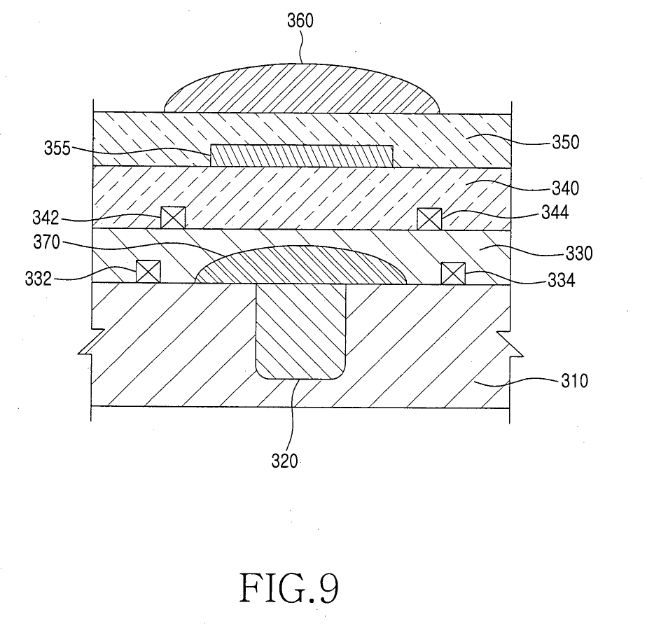

Referring to FIG. 9, the step S6 (of FIG. 3) represents a process of forming the first or exterior lens 360. In the step S6, the first lens 360 is formed on the third insulation layer 350 so that the first lens 360 is substantially optically aligned with the second lens 370.

As described above, the image sensor according to the present invention converges light into the photodiode region using the first lens formed thereon and the second lens embedded therein, thereby improving the light reception efficiency and reducing the cross-talk between adjacent pixels.

While the invention has been shown and described with reference to the preferred embodiments thereof, it will be understood by those skilled in the art that various changes in form and details may be made therein without departing from the spirit and scope of the invention as defined by the appended claims.

What is claimed is:

1. An image sensor comprising:
a substrate;
at least one insulation layer formed on the substrate; and
a plurality of pixels formed on the substrate, each of which includes:
a photodiode region formed in the substrate for performing an optical-electric conversion;
a first lens formed external to the at least one insulation layer for converging incident light; and
a second lens embedded in the at least one insulation layer so as to be disposed between the photodiode region and the first lens for converging the incident light.

2. The image sensor as claimed in claim 1, further comprising:
a color filter disposed between the first lens and the second lens so as to transmit light of predetermined color.

3. The image sensor as claimed in claim 1, further comprising:
at least one metal layer for electrical connection embedded in the insulation layer.

4. The image sensor as claimed in claim 1, further comprising:
a plurality of insulation layers formed on the substrate.

5. The image sensor as claimed in claim 4, further comprising:
a plurality of metal layers for electrical connection embedded in the insulation layers.

6. The image sensor as claimed in claim 1, wherein the image sensor is a complementary metal oxide semiconductor image sensor.

7. A method for fabricating a pixel element within an image sensor, the method comprising the steps of:
forming a photodiode region in a substrate, said photodiode region performing an optical-electric conversion;
forming on said substrate an interior lens optically aligned to said photodiode region and a first pair of electrodes outside the photodiode region;
encapsulating said lens and said first pair of electrodes in at least one insulating layer; and
forming a second lens on said at least one insulating layer, said second lens being optically aligned to said photodiode region.

8. The method as claimed in claim 7, further comprising the step of:
disposing a color filter between the second lens and the interior lens so as to transmit light of predetermined color to the interior lens.

9. The method as claimed in claim 7, wherein the first and second lens have a convex shape.

10. The method as claimed in claim 7, further comprising the step of:
embedding a second pair of electrodes in said at least one insulating layer, said second pair of electrodes being positioned outside the photodiode region.

11. An image sensor comprising a plurality of pixel elements, each of said pixel elements being fabricated by a method comprising the steps of:
creating within a substrate a photodiode region, said photodiode region performing an optical-electric conversion;
depositing on said substrate, an optically transparent material optically aligned with said photodiode region and a plurality of metal substantially parallel electrodes positioned outside said photodiode region;
embedding said optically transparent material and said metal electrodes in an insulating layer; and
depositing a second optically transparent material on said insulating layer optically aligned to said photodiode region.

12. The image sensor as recited in claim 11, wherein the method for fabricating said pixel element further comprising the step of:
embedding a color filter for selecting a desired color between said optically transparent optically material and said second optically transparent optically material.

13. The image sensor as recited in claim 11, wherein the optically transparent optically material and said second optically transparent optically material are shaped to focus an incident light onto said photodiode region.

14. The image sensor as recited in claim 13, wherein the material shape is convex.
